(19) United States
(12) Patent Application Publication
(10) Pub. No.: US 2025/0347618 A1
(43) Pub. Date: Nov. 13, 2025

(54) SEMICONDUCTOR MEASUREMENT APPARATUS

(71) Applicant: SAMSUNG ELECTRICS CO., LTD., Suwon-si (KR)

(72) Inventors: Ga Ram CHOI, Suwon-si (KR); Wook Rae Kim, Suwon-si (KR); Jin Seob Kim, Suwon-si (KR); Jin Yong Kim, Suwon-si (KR); Seung Woo Lee, Suwon-si (KR); Eun Joo Lee, Suwon-si (KR); Young Uk Jin, Suwon-si (KR); Jae Min Ha, Suwon-si (KR); Charles Soon Hong Hwang, Suwon-si (KR)

(73) Assignee: SAMSUNG ELECTRICS CO., LTD., Suwon-si (KR)

(21) Appl. No.: 18/934,953

(22) Filed: Nov. 1, 2024

(30) Foreign Application Priority Data
May 7, 2024 (KR) 10-2024-0059653

(51) Int. Cl. G01N 21/31

(52) U.S. Cl. CPC G01N 21/31; G01N 2201/0636

(57) ABSTRACT

Provided is a semiconductor measurement apparatus including a light source configured to emit light, a digital light processor configured to generate structured light based on the light emitted by the light source, a first polarizer configured to transmit the structured light, a second polarizer configured to transmit light reflected from a sample, passing through the first polarizer, a spectrometer configured to receive light transmitted through the second polarizer, and at least one processor configured to generate polarization data by analyzing the light received by the spectrometer.

### CROSS-REFERENCE TO RELATED APPLICATION

This application claims priority from Korean Patent Application No. 10-2024-0059653 filed on May 7, 2024 in the Korean Intellectual Property Office, the disclosure of which is incorporated herein in its entirety by reference.

### BACKGROUND

### 1. Field

Embodiments of the present disclosure relate to a semiconductor measurement apparatus.

### 2. Description of Related Art

Ellipsometry is an optical technique used to study the dielectric properties of wafers. Ellipsometry may also be referred to as the ellipsometric method. Ellipsometry may yield information regarding a sample (e.g., a wafer surface) by analyzing changes in the polarization of reflected light from the sample. For example, the polarization state of the reflected light varies depending on the optical properties of the material of the sample and the layer thickness of the sample. By measuring these changes in polarization, the ellipsometric method may determine fundamental physical quantities of materials, such as the complex refractive index or dielectric function tensor, and may derive sample information such the sample's shape, crystalline state, chemical structure, electrical conductivity, etc.

However, this ellipsometric method emits light on the sample at fixed azimuth and incidence angles, measuring the spectrum of the reflected light from the sample to gauge thickness and structural information. Since light is emitted at fixed azimuth and incidence angles, only limited information may be obtained. To compensate for this, elements such as a polarizer or compensator may be rotated hardware-wise. However, even with hardware rotation, measurements may only be made for some pre-set azimuth/incidence angles, which limits the type of information that may be obtained.

### SUMMARY

One or more embodiments provide a semiconductor measurement apparatus capable of measuring polarization information at various azimuth and incidence angles without rotating components hardware-wise.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of one or more embodiments, there is provided a semiconductor measurement apparatus including a light source configured to emit light, a digital light processor configured to generate structured light based on the light emitted by the light source, a first polarizer configured to transmit the structured light, a second polarizer configured to transmit light reflected from a sample, passing through the first polarizer, a spectrometer configured to receive light transmitted through the second polarizer, and at least one processor configured to generate polarization data by analyzing the light received by the spectrometer.

According to another aspect of one or more embodiments, there is provided a semiconductor measurement apparatus including a light source configured to emit light, a digital mirror device configured to generate structured light by the light emitted by the light source, a first polarizer configured to transmit the structured light, a second polarizer configured to transmit light reflected from the sample, passing through the first polarizer, a spectrometer configured to receive light passing through the second polarizer, and at least one processor configured to generate polarization data by analyzing the light received by the spectrometer, wherein the light emitted by the light source has a broadband wavelength ranging from ultraviolet to infrared, wherein the spectrometer includes a single pixel, wherein the semiconductor measurement apparatus further comprises a digital light processor configured to change into a plurality of patterns, wherein the spectrometer is further configured to receive a plurality of pattern images generated by a plurality of beams of structured light that correspond to the plurality of patterns, respectively, wherein each of the plurality of pattern images is a result of interference of a plurality of polarization components generated by the first polarizer and the second polarizer, and wherein the at least one processor is further configured to generate a measurement image based on the plurality of pattern images and generate a plurality of slice images by slicing the measurement image based on a plurality of wavelengths.

According to still another aspect of one or more embodiments, there is provided a semiconductor measurement apparatus including an illumination system configured to sequentially provide a plurality of structured light beams to a sample, a light-receiving system configured to obtain a plurality of pattern images generated by a reflection of the plurality of structured light beams from the sample onto a back focal plane of an objective lens, and at least one processor configured to generate a measurement image based on the plurality of pattern images, and to generate a plurality of slice images by slicing a measurement image based on a plurality of wavelengths.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail exemplary embodiments thereof with reference to the attached drawings, in which:

FIG. 1 is a block diagram illustrating a semiconductor measurement apparatus according to one or more embodiments;

FIG. 2 is a detailed view of the semiconductor measurement apparatus illustrated in FIG. 1;

FIG. 3 is a diagram for further explaining the semiconductor measurement apparatus illustrated in FIG. 1;

FIG. 4 is a flowchart illustrating a semiconductor measurement method according to one or more embodiments;

FIG. 5 is a conceptual diagram illustrating each step of FIG. 4;

FIG. 6 is a detailed flowchart illustrating step S10 of FIG. 4;

FIG. 7 is a detailed flowchart illustrating step S40 of FIG. 4;

FIGS. 8, 9, 10, 11, 12, and 13 are diagrams illustrating each step in FIG. 7;

FIG. 14 is a diagram illustrating a semiconductor measurement method according to one or more embodiments;

FIG. 15 is a diagram illustrating slice images with different resolutions; and

FIG. 16 is a diagram illustrating slice images with different resolutions for each region thereof.

### DETAILED DESCRIPTION

Embodiments of the present disclosure will hereinafter be described in detail with reference to the accompanying drawings. Embodiments described herein are example embodiments, and thus, the disclosure is not limited thereto. The same reference numerals are used for the same components in the drawings, and redundant descriptions thereof will be omitted.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

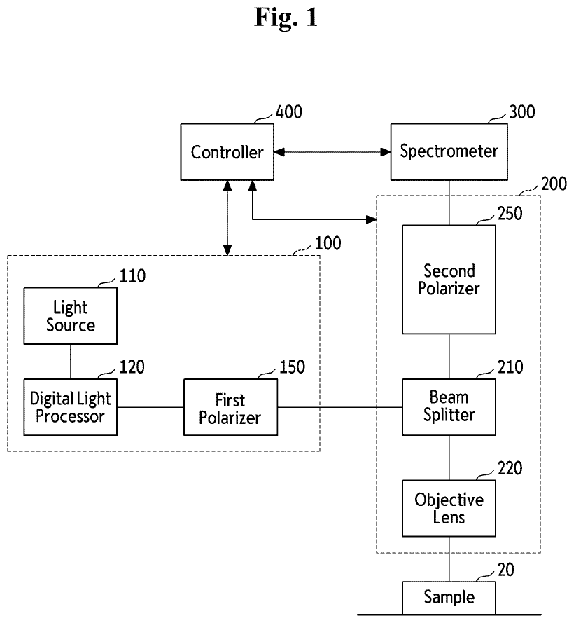

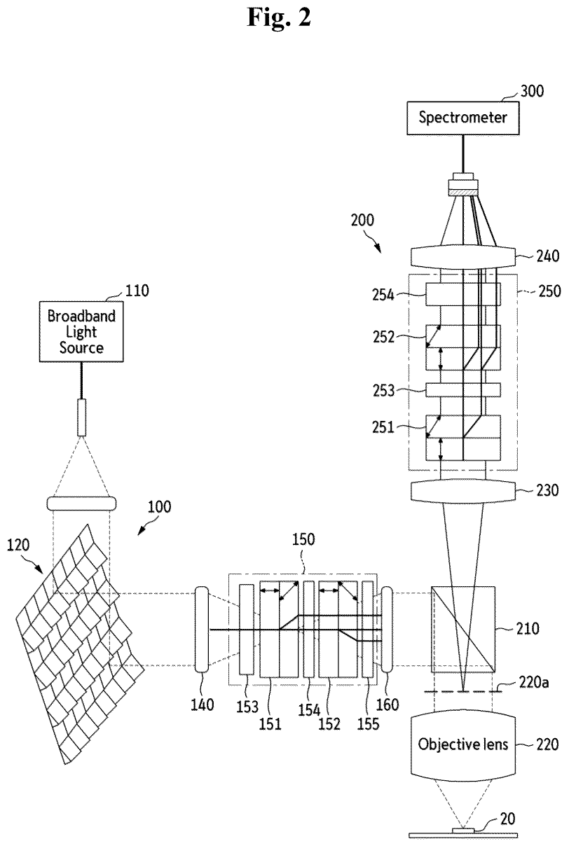

FIG. 1 is a block diagram illustrating a semiconductor measurement apparatus according to one or more embodiments. FIG. 2 is a detailed view of the semiconductor measurement apparatus illustrated in FIG. 1.

Referring to FIGS. 1 and 2, the semiconductor measurement apparatus according to one or more embodiments may include an illumination unit (illumination system) 100, an optical unit (optical system) 200, a spectrometer 300, and a controller 400. The optical unit 200 and the spectrometer 300 may be collectively referred to as a light receiving unit (light receiving system).

The illumination unit 100 includes a light source 110, a digital light processor 120, a first polarizer 150, and may further include a first illumination lens 140 and a second illumination lens 160.

The light source 110 emits light that is incident on a sample 20, and the light may be light that ranges from ultraviolet to infrared wavelengths.

The digital light processor 120 generates structured light using light emitted from the light source 110. For example, the digital light processor 120 may change into a plurality of patterns, and the light emitted from the light source 110 is reflected by the digital light processor 120, becoming a plurality of beams of structured light corresponding to the plurality of patterns. For example, when the digital light processor 120 is in a first pattern, the light reflected by the digital light processor 120 becomes first structured light. When the digital light processor 120 is in a second pattern different from the first pattern, the light reflected by the digital light processor 120 becomes second structured light different from the first structured light. An example of the digital light processor 120 may be a Digital Mirror Device (DMD), but embodiments are not limited thereto.

The structured light generated by the digital light processor 120 is delivered to the first polarizer 150 through the first illumination lens 140. The first polarizer 150 is disposed in the path of the structured light.

The first polarizer 150 polarizes the light that has passed through the first illumination lens 140 in a predetermined polarization direction and transmits the polarized light to be incident on the sample 20. In one or more embodiments, the first polarizer 150 may include at least one illumination polarization element and wave plates 154 and 155. For example, the first polarizer 150 may include a first illumination polarization element 151, a second illumination polarization element 152, and a third illumination polarization element 153. Each of the first and second illumination polarization elements 151 and 152 may include a pair of beam displacers, and the third illumination polarization element 153 may be a polarizer. The wave plates 154 and 155 may be half-wave plates or quarter-wave plates, and the numbers of illumination polarization elements and wave plates included in the first polarizer 150 may vary. For example, the first and second illumination polarization elements 151 and 152 may be implemented as Nomarski prisms, Wollaston prisms, and/or Rochon prisms. The third illumination polarization element 153 may polarize light at a polarization direction inclined by an angle of 45 degrees with respect to the ground, but embodiments are not limited thereto. The light passing through the first polarizer 150 is incident on a beam splitter 210 of the optical unit 200 through the second illumination lens 160, which may be implemented as a convex lens.

The optical unit 200 may form the light receiving unit together with the spectrometer 300. The light receiving unit may be an optical system configured to image a back focal plane 220a of an objective lens 220. The optical unit 200 may include the objective lens 220, the beam splitter 210, and a second polarizer 250. Additionally, the optical unit 200 may further include first and second relay lenses 230 and 240.

The beam splitter 210 may reflect some of the light received from the illumination unit 100 and transmit some of the light received from the illumination unit 100. The light reflected by the beam splitter 210 is incident on the objective lens 220, and the light passing through the objective lens 220 may be incident on the sample 20. For example, the light passing through the objective lens 220 may be incident so that it may be focused on a target area of the sample 20.

When the light passing through the objective lens 220 is reflected by the target area of the sample 20, the objective lens 220 may receive the reflected light again. As illustrated in FIG. 2, the optical axis of the light incident on and reflected by the sample 20 may be perpendicular to the surface of the sample 220.

The light reflected from the sample 20 passes sequentially through the objective lens 220, the beam splitter 210, the first relay lens 230, the second polarizer 250, and the second relay lens 240, and may be incident on the spectrometer 300.

The second polarizer 250 is disposed in the path of the light reflected from the sample 20. The second polarizer 250 may include at least one light-receiving polarization element, for example, a first light-receiving polarization element 251 and a second light-receiving polarization element 252, a wave plate 253, and an analyzer 254. The first and second light-receiving polarization elements 251 and 252 polarize light passing through the first relay lens 230 and may each include a pair of beam displacers. The wave plate 253, like the wave plates 154 and 155 included in the illumination unit 100, may be a half-wave plate, but embodiments are not limited thereto. The light passing through the second polarizer 250 may be incident on the spectrometer 300 through the second relay lens 240.

The first and second illumination polarization elements 151 and 152 may, for example, separate the incident light into four polarization components. Additionally, the first and second light-receiving polarization elements 251 and 252 may additionally separate the four polarization components into 16 polarization components, but embodiments are not limited thereto.

In the spectrometer 300, a plurality of polarization components generated by the first and second illumination polarization elements 151 and 152 and the first and second light-receiving polarization elements 251 and 252 may be incident, interfering with one another. The spectrometer 300 may include a single pixel.

Based on broadband light ranging from ultraviolet to infrared wavelengths, structured light is generated by the digital light processor 120. The structured light is reflected by the sample 20 and delivered to the spectrometer 300. For example, the structured light becomes beams separated into four components by the first and second illumination polarization elements 151 and 152, the separated beams are incident on the sample 20, and the light reflected from the sample 20 becomes beams separated into 16 components by the first and second light-receiving polarization elements 251 and 252, and the separated beams are provided to the spectrometer 300. The separated beams are recombined in the spectrometer 300 to create a multiple-interference image.

The controller 400 generates polarization data by analyzing the light received by the spectrometer 300.

For example, the digital light processor 120 changes into a plurality of patterns, and a plurality of beams of structured lights respectively corresponding to the plurality of patterns are generated. As the beams of structured light are reflected from the sample 20 and are then incident on the spectrometer 300, the spectrometer 300 receives a plurality of pattern images. The controller 400 combines the pattern images to create a measurement image. The controller 400 generates a plurality of slice images by slicing the measurement image according to a plurality of wavelengths. The wavelengths for generating the slice images may be selectively determined by a user according to a purpose intended by the user.

Subsequently, the controller 400 may perform a frequency transform on each of the slice images and may select regions indicated by peaks caused by the interference of a plurality of polarization components. The controller 400 may acquire a plurality of sample images by performing an inverse frequency transform on each of the selected regions, and may determine a plurality of elements forming an N×N matrix using the sample images. As an example, the N×N matrix may be a Mueller matrix, and N may be determined according to the number of polarization elements included in the semiconductor measurement apparatus according to one or more embodiments. In an embodiment depicted in FIG. 2, since the illumination unit 100 includes the first and second illumination polarization elements 151 and 152 and the optical unit 200 includes the first and second light-receiving polarization elements 251 and 252, the controller 400 may generate a plurality of elements included in a 4×4 matrix.

The pattern images corresponding to the respective beams of structured light are generated based on light (i.e., broadband light) ranging from ultraviolet to infrared wavelengths. These beams of structured light are provided to the sample 20 through the objective lens 220, and polarization information (or polarization data) of light reflected from all angles surrounding the sample 20 may be acquired. The controller 400 may analyze this polarization information to measure structural information, thereby obtaining complete angle/polarization information necessary for structural measurement.

Additionally, by securing complete information of the light reflected from the sample 20, it is possible to achieve a measurement sensitivity of 0.1 nm and overcome structural correlation limits.

Furthermore, polarization data at various incidence/azimuth angles may be measured without driving polarizers or other hardware elements.

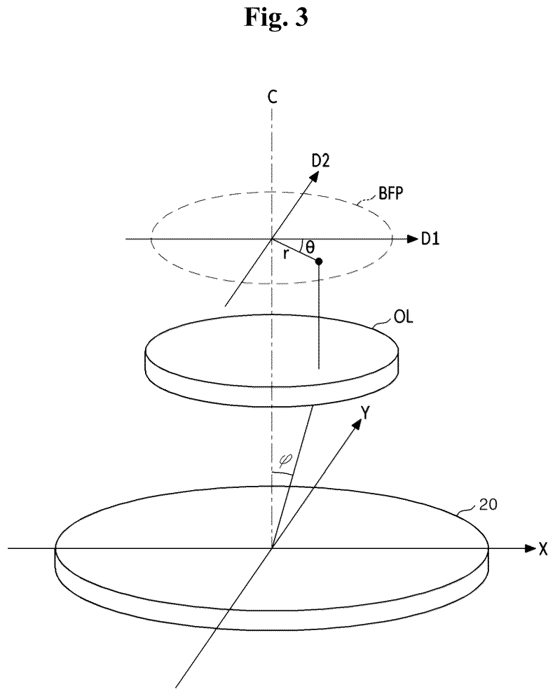

FIG. 3 is a diagram for further explaining the semiconductor measurement apparatus illustrated in FIG. 1.

Referring to FIG. 3, light may be emitted onto the surface of the sample 20, and the surface of the sample 20 may be defined as an XY plane. An optical axis C extends from the origin of the XY plane and may extend in a direction perpendicular to the XY plane, and the center of an objective lens OL adjacent to the sample 20 may correspond to the optical axis C. The objective lens OL includes a front side facing the sample 20 and a rear side located opposite to the sample 20, and a back focal plane BFP (corresponding to the back focal plane 220a in FIG. 2) may be defined at a predetermined distance from the rear side of the objective lens OL.

The back focal plane BFP may be a plane defined by a first direction D1 and a second direction D2. For example, the first and second directions D1 and D2 may be the same as the X- and Y-axis directions, respectively, of the surface of the sample 20. The light passing through the objective lens OL is focused as a point on the target area of the sample 20, is reflected again from the target area, and passes through the objective lens OL to proceed to the back focal plane BFP. As previously described, in the semiconductor measurement apparatus according to one or more embodiments, light may be incident on the sample 20 at all azimuth angles from 0 to 360 degrees, and the range of an incidence angle φ of the light incident on the sample 20 may be determined by the numerical aperture of the objective lens OL.

In one or more embodiments, an objective lens OL having a numerical aperture of 0.95 or more and less than 1.0 may be employed in the semiconductor measurement apparatus according to one or more embodiments to obtain data for a wide range of incidence angles in a single shot executed by the spectrometer 300. In this case, the maximum incidence angle of the light passing through the objective lens OL may be 72 degrees or more and less than 90 degrees. As an example, the spectrometer 300 may be arranged such that its surface receiving light may be positioned at a conjugate position with respect to the back focal plane BFP of the objective lens OL.

Each position included in the back focal plane BFP defined by the first and second directions D1 and D2 may be represented as polar coordinates (r, 0). Here, the first coordinate r may be determined by the incidence angle φ, and the second coordinate θ indicates how much each position has rotated based on the first direction D1 and may be the same as the azimuth angle of the light incident on the sample 20, ranging from 0 degrees to 360 degrees.

Consequently, in the semiconductor measurement apparatus according to one or more embodiments, data including the interference patterns of azimuth angles from 0 degrees to 360 degrees and the incidence angle range determined by the numerical aperture of the objective lens OL may be obtained in the form of an image through a single shot during the reflection of light from the target area of the sample 20. Therefore, unlike a conventional method that requires multiple shots while adjusting the position and angle of the illumination unit 100 irradiating light on the sample 20 or of the sample 20 itself, the data necessary for analyzing and measuring the target area of the sample 20 may be obtained in a single shot, thereby improving the efficiency of the measurement process using the semiconductor measurement apparatus according to one or more embodiments.

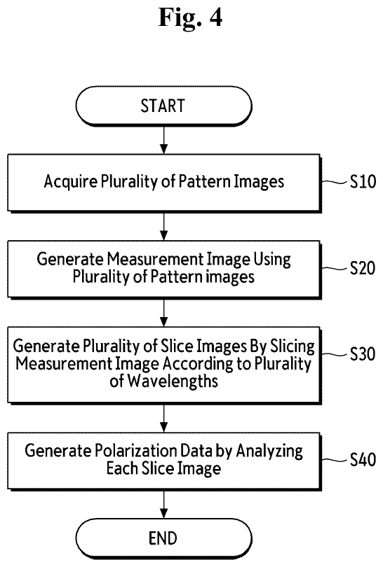

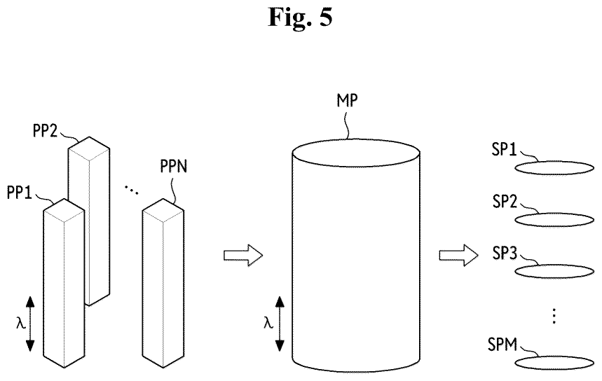

FIG. 4 is a flowchart illustrating a semiconductor measurement method according to one or more embodiments. FIG. 5 is a conceptual diagram illustrating each step of FIG. 4.

Referring to FIGS. 4 and 5, in step S10, a plurality of pattern images PP1 through PPN (where N is a natural number greater than or equal to 3) are obtained.

For example, the digital light processor 120 of FIG. 1 generates structured light using broadband light emitted by the light source 110 of FIG. 1. For example, the digital light processor 120 may change into a plurality of patterns, and the light emitted from the light source 110 may be reflected by the digital light processor 120, becoming a plurality of beams of structured light respectively corresponding to the plurality of patterns. The pattern images PP1 through PPN generated by the reflection of the respective beams of structured light from the sample 20 are provided to the spectrometer 300 of FIG. 1.

Thereafter, in step S20, a measurement image MP is generated using the pattern images PP1 through PPN.

For example, the controller 500 of FIG. 1 combines the pattern images PP1 through PPN to complete the measurement image MP. Since the pattern images PP1 through PPN and the measurement image MP are generated based on broadband structured light, they include image data corresponding to the entire broadband wavelength λ.

Then, in step S30, a plurality of slice images SP1 through SPM (where M is a natural number greater than or equal to 3) are generated by slicing the measurement image MP according to a plurality of wavelengths.

For example, since the measurement image MP includes image data for the entire broadband wavelength λ, the controller 400 may generate the slice images SP1 through SPM by slicing slice the measurement image MP at specific wavelengths needed for analysis.

In FIG. 5, as an example, the pattern images PPI through PPN are illustrated as rectangular prisms, the measurement image MP as a cylinder, and the slice images SP1 through SPM as disks, but embodiments are not limited thereto.

Thereafter, in step S40, polarization data is generated by analyzing each of the slice images SP1 through SPM.

The polarization data may be, for example, a Mueller matrix, but embodiments are not limited thereto. Each element of the Mueller matrix may be in the form of three-dimensional (3D) image format data.

The Mueller matrix is a matrix used to handle Stokes vectors representing the polarization components of light. The Mueller matrix may represent the light incident on the spectrometer 300 with 16 elements. As an example, the Mueller matrix may be a 4×4 matrix, and the total intensity of light incident on each pixel of the spectrometer 300 may be represented by the elements included in the Mueller matrix.

In one or more embodiments, the controller 400 may select 16 regions showing peaks caused by interference in each of the slice images SP1 through SPM and generate 16 sample images corresponding to the 16 regions. Additionally, the controller 400 may determine the elements of the Mueller matrix that may represent the 16 sample images.

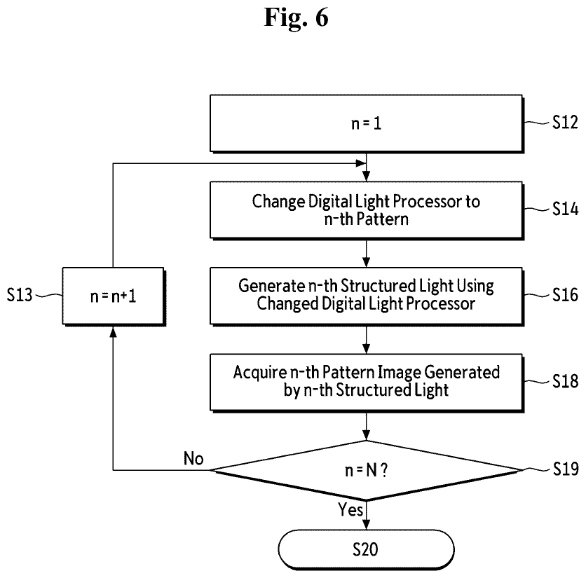

The step of obtaining a plurality of pattern images, i.e., step S10 of FIG. 4, will hereinafter be described with reference to FIG. 6. FIG. 6 is a detailed flowchart illustrating step S10 of FIG. 4.

Referring to FIG. 6, in step S12, n is set to 1.

Thereafter, in step S14, the digital light processor 120 of FIG. 1 is changed to an n-th pattern.

Thereafter, in step S16, an n-th beam of structured light is generated using the changed digital light processor 120.

Thereafter, the n-th structured light passes through the first polarizer 150 of FIG. 1, the sample 20, and the second polarizer 250, and is then provided to the spectrometer 300 as a pattern image PPn.

Thereafter, in S19, a determination is made as to whether n is equal to N, the preset target value (where N is a natural number greater than or equal to 3).

In step n and N are not equal in step S19, n is increased by 1 (i.e., n=n+1) (S13). Thereafter, steps S14, S16, and S18 are repeated.

When n and N are equal in step S19 (i.e., when a total of N pattern images PP1 through PPN have been obtained), the semiconductor measurement method according to some embodiments proceeds to step S20.

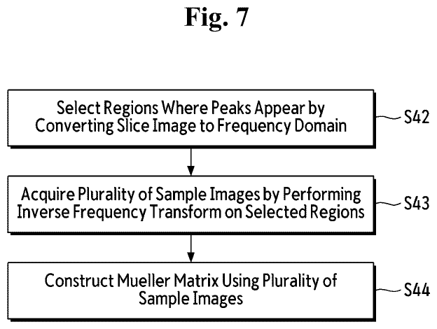

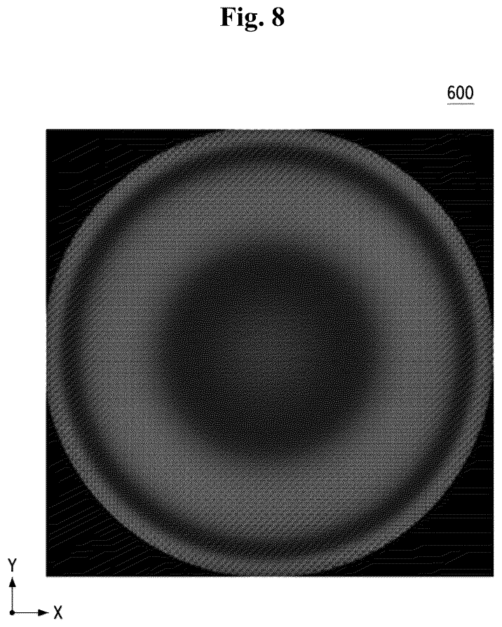

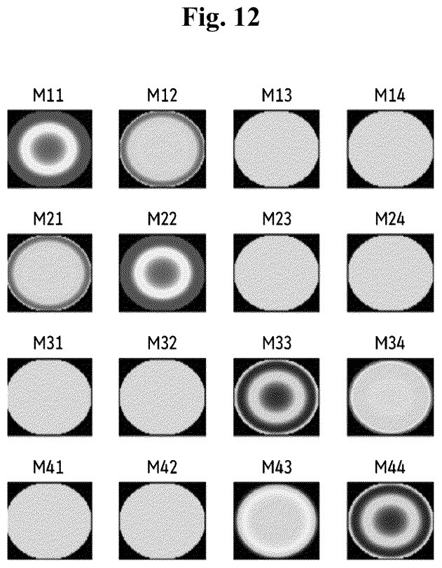

The step of generating polarization data, i.e., S40 of FIG. 4, will hereinafter be described with reference to FIGS. 7 through 14. FIG. 7 is a detailed flowchart illustrating step S40 of FIG. 4. FIGS. 8 through 13 are diagrams illustrating each step in FIG. 7.

Referring to FIG. 7, in step S42, the controller 400 performs a frequency transform on each of the slice images SP1 through SPM to select regions where peaks appear.

For example, each of the slice images SP1 through SPM may be an image representing the interference pattern of the polarization components of light generated by the polarization elements included in the semiconductor measurement apparatus according to one or more embodiments. FIG. 8 is a diagram showing an exemplary slice image 600. The slice image 600 may be a multi-interference image.

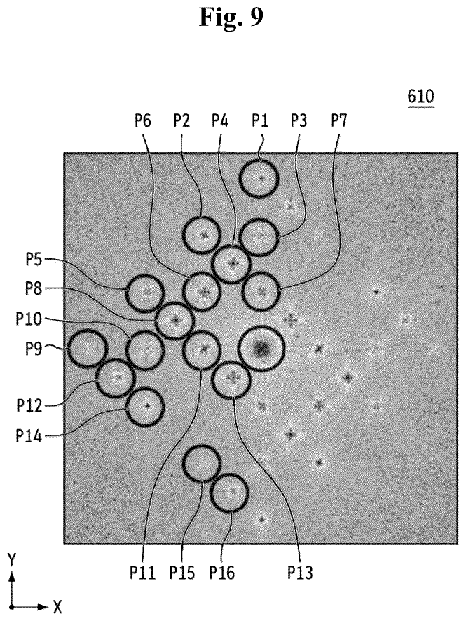

The controller 400 processes the slice image 600 to select regions where peaks appear due to the interference of at least some of the polarization components. For example, the controller 400 converts the slice image 600 to the frequency domain. Here, Fourier transform may be used, but embodiments are not limited thereto. FIG. 9 is a diagram illustrating an exemplary frequency-transformed image 610 obtained by converting the slice image 600 to the frequency domain. The controller 400 selects peaks caused by interference in the frequency-transformed image 610.

The regions where peaks appear may be distributed symmetrically 180 degrees around the origin, which is the center of the frequency-transformed image 610. The controller 400 may select regions where peaks appear without duplication. For example, referring to FIG. 9, the controller 400 may select a plurality of regions P1 through P16, which are symmetrically distributed at 180 degrees around the origin. In the regions P1 through P16, peaks may appear due to the interference of at least two polarization components decomposed by the polarization elements included in the semiconductor measurement apparatus according to one or more embodiments. For example, the controller 400 may select 16 regions P1 through P16 where peaks appear.

Referring back to FIG. 7, in step S43, the controller 400 acquire (obtain) a plurality of sample images by performing an inverse frequency transform on the selected regions.

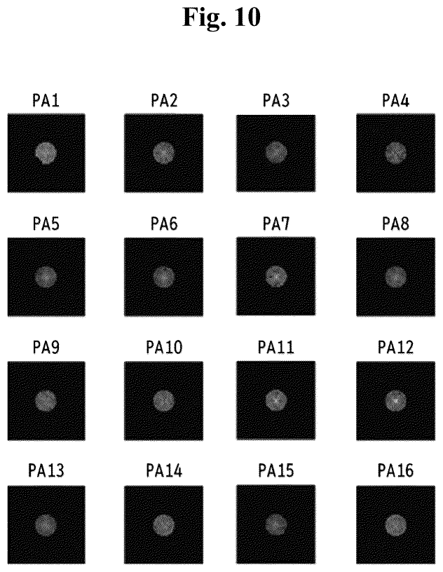

For example, FIG. 10 is a diagram illustrating data generated by the controller of the semiconductor measurement apparatus according to one or more embodiments through the separation of the regions P1 through P16 from the frequency-transformed image 610. The controller 400 filters the regions P1 through P16 in the frequency-transformed image 610 and acquires a plurality of data (or peak images) PA1 through PA16, as shown in FIG. 10 by performing an operation such as centering, which positions each detected peak at the center of a corresponding selected region. The data PA1 through PA16 may correspond to the regions (or positions) P1 through P16, respectively, included in the frequency-transformed image 610.

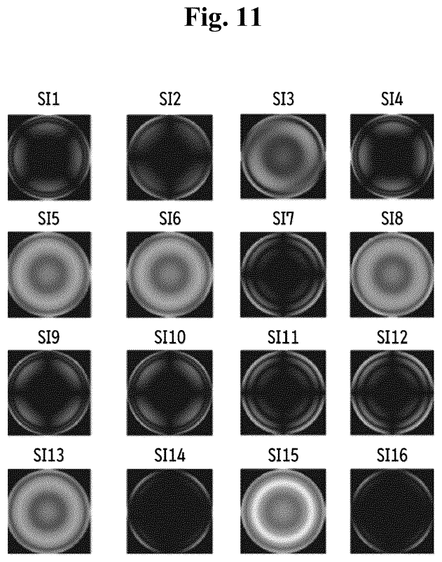

Thereafter, the controller 400 acquires a plurality of sample images SI1 through SI16, as shown in FIG. 11, by performing an inverse frequency transform on the data PA1 through PA16. Here, inverse Fourier transform may be used. The sample images SI1 through SI16 may be images representing the interference patterns of polarization components. For example, the sample images SI1 through SI16 may be images representing the states of at least some of the polarization components that are decomposed by the polarization elements included in the illumination unit 100 and optical unit 120, and that are incident on the spectrometer 300, interfering with one another.

Referring back to FIG. 7, in step S44, the controller 400 constructs a Mueller matrix using the sample images acquired in step S43.

For example, the controller 400 may determine the elements of the Mueller matrix using the sample images SI1 through SI16. For example, the Mueller matrix may include 16 elements M11 through M44. In the one or more embodiments described above with reference to FIGS. 8 through 11, 16 sample images, i.e., the sample images SI1 through SI16, may be acquired from one slice image 600, and the elements M11 through M44 that construct the Mueller matrix may be determined using the sample images SI1 through SI16.

Each of the sample images SI1 through SI16, which represent the interferences of at least some of the polarization components of the light reflected from the sample 20, may be defined as a polynomial including at least one of the elements of the Mueller matrix. Therefore, the elements M11 to M44 of the Mueller matrix may be determined inversely using the sample images SI1 through SI16. For example, the correspondence between the sample images SI1 through SI16 and the elements M11 through M44 of the Mueller matrix may be as shown in Table 1 below.

TABLE 1

| Position | X Coordinate | Y Coordinate | Real Part | Imaginary Part |
|---|---|---|---|---|
| 1 | 0 | 6y | $\frac{1}{32} ( {M}_{33} - {M}_{44} )$ | $- \frac{1}{32} ( {M}_{34} - {M}_{43} )$ |
| 2 | 2x | 4y | $\frac{1}{32} ( 2 {M}_{23} - {M}_{33} + {M}_{44} )$ | $\frac{1}{32} ( - 2 {M}_{24} + {M}_{34} + {M}_{43} )$ |
| 3 | 0 | 4y | $\frac{1}{8} {M}_{31}$ | $- \frac{1}{8} {M}_{41}$ |
| 4 | x | 3y | $\frac{1}{16} ( 2 {M}_{22} + {M}_{32} )$ | $- \frac{1}{16} {M}_{42}$ |
| 5 | 4x | 2y | $- \frac{1}{32} ( 2 {M}_{23} + {M}_{33} + {M}_{44} )$ | $\frac{1}{32} ( 2 {M}_{24} + {M}_{34} + {M}_{43} )$ |
| 6 | 2x | 2y | $\frac{1}{4} {M}_{21}$ | 0 |
| 7 | 0 | 2y | $\frac{1}{32} ( 4 {M}_{13} - 2 {M}_{23} + {M}_{33} + {M}_{44} )$ | $- \frac{1}{32} ( 4 {M}_{14} + 2 {M}_{24} - {M}_{34} + {M}_{43} )$ |
| 8 | 3x | y | $\frac{1}{16} ( 2 {M}_{22} - {M}_{32} )$ | $- \frac{1}{16} {M}_{42}$ |
| 9 | 6x | 0 | $\frac{1}{32} ( {M}_{33} + {M}_{44} )$ | $- \frac{1}{32} ( {M}_{34} - {M}_{43} )$ |
| 10 | 4x | 0 | $- \frac{1}{8} {M}_{31}$ | $- \frac{1}{8} {M}_{41}$ |
| 11 | 2x | 0 | $\frac{1}{32} ( 4 {M}_{13} - 2 {M}_{23} - {M}_{33} + {M}_{44} )$ | $\frac{1}{32} ( 4 {M}_{14} + 2 {M}_{24} + {M}_{34} + {M}_{43} )$ |
| 12 | 5x | −y | $- \frac{1}{16} {M}_{32}$ | $- \frac{1}{16} {M}_{42}$ |
| 13 | x | −y | $\frac{1}{4} {M}_{12}$ | 0 |
| 14 | 4x | −2y | $- \frac{1}{32} ( {M}_{33} - {M}_{44} )$ | $- \frac{1}{32} ( {M}_{34} + {M}_{43} )$ |
| 15 | 2x | −4y | $- \frac{1}{32} ( {M}_{33} + {M}_{44} )$ | $\frac{1}{32} ( {M}_{34} - {M}_{43} )$ |
| 16 | x | 5y | $\frac{1}{16} {M}_{32}$ | $\frac{1}{16} {M}_{42}$ |

As shown in Table 1 above, the elements M11 through M44 of the Mueller matrix may be calculated using the sample images SI1 through SI16. The Mueller matrix is a matrix used to handle Stokes vectors, and using the Stokes vectors, various measurement parameters, such as polarization degrees in addition to intensity differences and phase differences of polarization components, may be acquired. Therefore, by using the elements M11 through M44, various measurement parameters representing the characteristics of the polarization components may be calculated, enabling accurate determination of selected critical dimensions.

The controller 400 may also determine the selected critical dimensions by selecting at least one of the elements M11 through M44 and comparing the selected element(s) with reference data included in library data. In this case, the controller 400 may compare at least one element, which is data in image format, with the reference data, which is also data in image format. The library data may store reference data that appears as different images depending on the values of the selected critical dimensions. The controller 400 may determine the selected critical dimensions by referring to the most similar reference data to the selected element(s).

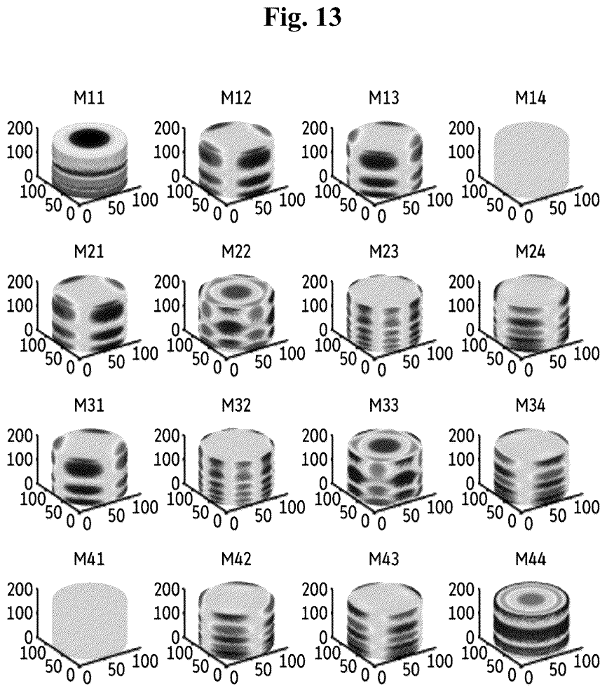

As the controller 400 repeatedly performs step S40 of FIG. 4 (refer to FIGS. 7 through 12), elements M11 through M44 in the form of 3D image format data may be acquired, as shown in FIG. 13.

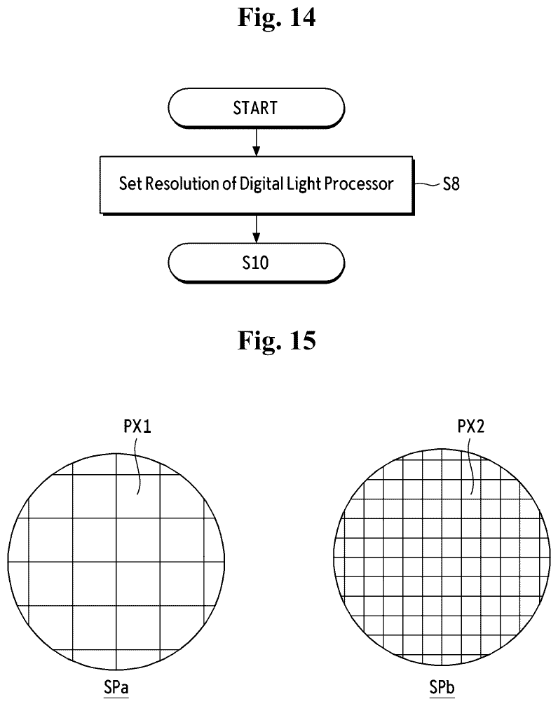

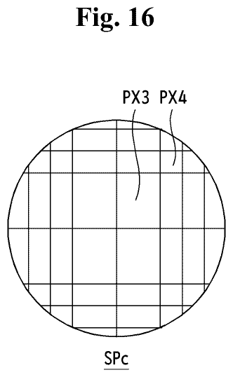

FIG. 14 is a diagram illustrating a semiconductor measurement method according to one or more embodiments. FIG. 15 is a diagram illustrating slice images with different resolutions. FIG. 16 is a diagram illustrating slice images with different resolutions for each region thereof.

Referring to FIG. 14, in step S8, prior to the acquisition of a plurality of pattern images, i.e., step S10 of FIG. 4, the resolution of the digital light processor 120 may be set.

In a related ellipsometric method, since the resolution of cameras is predetermined, even when high-resolution images are unnecessary, it is essential to obtain and analyze high-resolution images, which is time-consuming.

According to one or more embodiments, the spectrometer 300 may have a single pixel, and its resolution may be adjusted by adjusting the resolution of the digital light processor 120.

For example, when a low-resolution slice image is sufficient and a fast image acquisition speed is required, the resolution of the digital light processor 120 may be set low. In this case, as illustrated in FIG. 15, a slice image SPa with large-sized pixels PX1 may be acquired.

When a high-resolution slice image is required regardless of the image acquisition speed, the resolution of the digital light processor 120 may be set high. In this case, as illustrated in FIG. 15, a slice image SPb with small-sized pixels PX2 may be acquired.

Therefore, the digital light processor 120 forms a first pattern for implementing a first resolution for a first process section. For a second process section different from the first process section, the digital light processor 120 may form a second pattern for implementing a second resolution. Accordingly, slice images with different resolutions, e.g., the slice images SPa and SPb, may be acquired for different process sections.

Furthermore, a single slice image may have different resolutions in different regions thereof. For example, by setting the digital light processor 120, a first region of a slice image may be configured to have a first resolution, and a second region of the slice image, different from the first region, may be configured to have a second resolution different from the first resolution.

For example, as illustrated in FIG. 16, the edge region of a slice image SPc may be set to a relatively high resolution, and the center region of the slice image Spc may be set to a relatively low resolution that is lower than the resolution of the slice image SPc at the edge region. As a result, the edge region of the slice image SPc may have relatively small-sized pixels PX4, and the center region of the slice image SPc may have relatively large-sized pixels PX3.

However, embodiments are not limited thereto, and, for example, the center region of the slice image SPc may have relatively small-sized pixels, and the edge region of the slice image SPc may have relatively large-sized pixels.

By using light ranging from ultraviolet to infrared wavelengths and a high-speed digital light processor 120, relatively high-resolution images may be more efficiently acquired only when necessary.

At least one of the components, elements, modules or units (collectively “components” in this paragraph) represented by a block in the drawings, such as the controller 400 in FIG. 1, may be embodied as various numbers of hardware, software and/or firmware structures that execute respective functions described above, according to an exemplary embodiment. For example, at least one of these components may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU) that performs the respective functions, a microprocessor, or the like. Two or more of these components may be combined into one single component which performs all operations or functions of the combined two or more components. Also, at least part of functions of at least one of these components may be performed by another of these components. Further, although a bus is not illustrated in the above block diagrams, communication between the components may be performed through the bus. Functional aspects of the above exemplary embodiments may be implemented in algorithms that execute on one or more processors. Furthermore, the components represented by a block or processing steps may employ any number of related art techniques for electronics configuration, signal processing and/or control, data processing and the like.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor measurement apparatus comprising:
a light source configured to emit light;
a digital light processor configured to generate structured light based on the light emitted by the light source;
a first polarizer configured to transmit the structured light;
a second polarizer configured to transmit light reflected from a sample, passing through the first polarizer;
a spectrometer configured to receive light transmitted through the second polarizer; and
at least one processor configured to generate polarization data by analyzing the light received by the spectrometer.

2. The semiconductor measurement apparatus of claim 1, wherein the light emitted by the light source has a broadband wavelength ranging from ultraviolet to infrared.

3. The semiconductor measurement apparatus of claim 1, wherein the spectrometer comprises a single pixel.

4. The semiconductor measurement apparatus of claim 1, wherein the digital light processor is further configured to change into a plurality of patterns,
wherein the spectrometer is further configured to receive a plurality of pattern images generated by a plurality of beams of structured light that correspond to the plurality of patterns, respectively, and
wherein the at least one processor is further configured to generate a measurement image based on the plurality of pattern images.

5. The semiconductor measurement apparatus of claim 4, wherein the at least one processor is further configured to generate a plurality of slice images by slicing the measurement image based on a plurality of wavelengths.

6. The semiconductor measurement apparatus of claim 5, wherein a first region of a slice image of the plurality of slice images has a first resolution, and
a second region of a slice image of the plurality of slice images, different from the first region, has a second resolution different from the first resolution.

7. The semiconductor measurement apparatus of claim 1, wherein the digital light processor is further configured to form a first pattern to implement a first resolution in a first process section, and form a second pattern to implement a second resolution in a second process section different from the first process section.

8. The semiconductor measurement apparatus of claim 1, wherein the at least one processor is further configured to:
generate a slice image by analyzing the light received by the spectrometer;
extract a plurality of peak images corresponding to regions where peaks appear based on the interference of polarization components that have passed through the first polarizer and the second polarizer, by converting the slice image to a frequency domain; and
obtain a plurality of sample images by performing an inverse frequency transform on each of the plurality of peak images.

9. The semiconductor measurement apparatus of claim 8, wherein the at least one processor is further configured to obtain a Mueller matrix including a plurality of elements based on the plurality of sample images.

10. The semiconductor measurement apparatus of claim 9, wherein each of the plurality of elements is in three-dimensional (3D) image format data.

11. The semiconductor measurement apparatus of claim 1, wherein the digital light processor includes a digital mirror device (DMD).

12. The semiconductor measurement apparatus of claim 1, wherein the first polarizer comprises a first illumination polarization element and a second illumination polarization element,
wherein each of the first illumination polarization element and the second illumination polarization element comprises a pair of beam displacers,
wherein the second polarizer comprises a first light-receiving polarization element and a second light-receiving polarization element, and
wherein each of the first light-receiving polarization element and the second light-receiving polarization element comprises a pair of beam displacers.

13. The semiconductor measurement apparatus of claim 1, further comprising an objective lens configured to deliver light to the sample,
wherein the objective lens has a numerical aperture greater than or equal to 0.95 and less than 1.0.

14. The semiconductor measurement apparatus of claim 13, wherein the second polarizer, the spectrometer, and the objective lens are implemented as an optical system configured to image a back focal plane of the objective lens.

15. A semiconductor measurement apparatus comprising:
a light source configured to emit light;
a digital mirror device configured to generate structured light by the light emitted by the light source;
a first polarizer configured to transmit the structured light;
a second polarizer configured to transmit light reflected from the sample, passing through the first polarizer;
a spectrometer configured to receive light passing through the second polarizer; and
at least one processor configured to generate polarization data by analyzing the light received by the spectrometer,
wherein the light emitted by the light source has a broadband wavelength ranging from ultraviolet to infrared,
wherein the spectrometer comprises a single pixel,
wherein the semiconductor measurement apparatus further comprises a digital light processor configured to change into a plurality of patterns,
wherein the spectrometer is further configured to receive a plurality of pattern images generated by a plurality of beams of structured light that correspond to the plurality of patterns, respectively,
wherein each of the plurality of pattern images is a result of interference of a plurality of polarization components generated by the first polarizer and the second polarizer, and
wherein the at least one processor is further configured to generate a measurement image based on the plurality of pattern images and generate a plurality of slice images by slicing the measurement image based on a plurality of wavelengths.

16. The semiconductor measurement apparatus of claim 15, wherein the at least one processor is further configured to:
extract a plurality of peak images corresponding to regions where peaks appear based on the interference of polarization components that have passed through the first polarizer and the second polarizer, by converting the slice image to a frequency domain; and
obtain a plurality of sample images by performing an inverse frequency transform on each of the plurality of peak images.

17. The semiconductor measurement apparatus of claim 16, wherein the at least one processor is further configured to obtain a Mueller matrix comprising a plurality of elements based on the plurality of sample images, and
wherein each of the plurality of elements is in three-dimensional (3D) image format data.

18. The semiconductor measurement apparatus of claim 15, further comprising:
an objective lens configured to transmit light to the sample,
wherein the second polarizer, the spectrometer, and the object lens are implemented as an optical system configured to image a back focal plane of the objective lens.

19. A semiconductor measurement apparatus comprising:
an illumination system configured to sequentially provide a plurality of structured light beams to a sample;
a light-receiving system configured to obtain a plurality of pattern images generated by a reflection of the plurality of structured light beams from the sample onto a back focal plane of an objective lens; and
at least one processor configured to generate a measurement image based on the plurality of pattern images, and to generate a plurality of slice images by slicing a measurement image based on a plurality of wavelengths.

20. The semiconductor measurement apparatus of claim 19, wherein the plurality of structured light beams are generated by a digital mirror device (DMD) configured to change into a plurality of patterns based on light having a broadband wavelength, ranging from ultraviolet to infrared, and
wherein the light-receiving system comprises a spectrometer, which includes a single pixel and is configured to receive the plurality of pattern images.
